(19) United States
(12) Patent Application Publication
(10) Pub. No.: US 2012/0308355 A1
(43) Pub. Date: Dec. 6, 2012

(54) MOTOR, ROBOT HAND, AND ROBOT

(75) Inventors: Shinji YASUKAWA, Shiojiri (JP); Osamu MIYAZAWA, Shimosuwa (JP)

(73) Assignee: SEIKO EPSON CORPORATION, Tokyo (JP)

(21) Appl. No.: 13/484,738

(22) Filed: May 31, 2012

(30) Foreign Application Priority Data
Jun. 3, 2011 (JP) 2011-125103

(51) Int. Cl. B25J 18/00; H01L 41/00; B25J 15/02

(52) U.S. Cl. 414/729; 294/213; 310/328

(57) ABSTRACT

A motor includes: a driven unit having a cylindrical shape; an actuator having a protrusion abutting on the driven unit; and an impelling unit impelling the actuator against the driven unit, wherein, assuming that the trajectory of the protrusion is disposed to abut on a side surface of the cylindrical shape at a contact point P and a point of action where an impelling force is exerted on the actuator is a point of action Q, the relation between an angle θ1 between the impelling direction of the impelling unit and a direction connecting a rotational center R of the driven unit and the contact point P and an angle θ2 between the impelling direction of the impelling unit and a direction connecting the contact point P and the point of action Q satisfy a relationship of θ1<θ2.

### BACKGROUND

1. Technical Field

The invention relates to a motor, a robot hand, and a robot.

2. Related Art

As a motor that drives a driven body using vibration of a piezoelectric element, a motor is known that drives a driven body by causing a protrusion of a reinforcement plate of an actuator in which a rectangular flat plate-like piezoelectric element is laminated on the reinforcement plate having the protrusion integrally formed to abut on the driven body (JP-A-2010-233335). Ina motor having this piezoelectric actuator, an impelling unit is included for causing the protrusion provided in the reinforcement plate of the piezoelectric actuator to abut on the driven body, and frictional force between the protrusion of the reinforcement plate and the driven body, which is caused by the impelling force generated by the impelling unit transmits vibration of the protrusion of the reinforcement plate tracing a substantially elliptical trajectory to the driven body, thereby driving the driven body in a predetermined direction.

In JP-A-2010-233335 described above, in order for the impelling unit to impel the protrusion of the reinforcement plate against the rotational center of the driven body, spring members are disposed on both sides of the piezoelectric actuator including the reinforcement plate. However, since the protrusion of the reinforcement plate operates in a substantially elliptical trajectory, the reaction force on the protrusion of the reinforcement plate from the driven body by the impelling force is generated in a direction intersecting the direction of the impelling force toward the rotational center of the driven body. Due to the reaction force intersecting the direction of the impelling force, the operation of the protrusion of the reinforcement plate does not trace the desired elliptical trajectory. That is, there is a problem in that the reaction force becomes a cause of degradation of the efficiency in changing the vibration of the actuator into the driving force of the driven body.

### SUMMARY

An advantage of some aspects of the invention is that it provides a motor with good efficiency using an impelling unit that does not cause the reaction force of an actuator from a driven unit to impede conversion of vibration of the actuator into the driving force of the driven unit, a robot hand using the motor, and a robot.

### Application Example 1

This application example of the invention is directed to a motor including: a driven unit having a cylindrical rotation surface; an actuator including a vibrator plate having, on an end portion, a protrusion impelled against the rotation surface of the driven unit, and a piezoelectric body laminated on the vibrator plate; and an impelling unit impelling the actuator against the driven unit, wherein, assuming that the elliptical trajectory of the protrusion traced by vibration of the actuator that drives the driven unit is disposed to abut on the rotation surface, a contact point between the elliptical trajectory and the rotation surface is a contact point P, a point of action where an impelling force by the impelling unit is exerted on the actuator is a point of action Q, and a rotational center of the driven unit is a rotational center R, an angle θ1 between the impelling direction of the impelling unit and a direction connecting the rotational center R and the contact point P and an angle θ2 between the impelling direction of the impelling unit and a direction connecting the contact point P and the point of action Q satisfy the following relationship.

θ1<θ2

According to the above-described application example, by causing the angles θ1 and θ2 to have the above relationship, a component force of the reaction force exerted on the protrusion of the vibrator plate from the driven unit so as not to cause the protrusion of the vibrator plate to be directed to the rotational center of the driven unit is suppressed, so that the vibration of the excited actuator may be converted into the rotational force of the driven unit with a high efficiency.

### Application Example 2

This application example of the invention is directed to a robot hand including the motor according to the above-described application example.

The robot hand according to this application example has a high degree of freedom and thus can achieve a reduction in size and weight even though a large number of motors are included therein.

### Application Example 3

This application example of the invention is directed to a robot including the robot hand according to the above-described application example.

The robot hand according to this application example has a high degree of versatility and is able to perform an assembly operation or inspection on a complex electronic device.

### BRIEF DESCRIPTION OF THE DRAWINGS

The invention will be described with reference to the accompanying drawings, wherein like numbers reference like elements.

FIG. 1 is an exploded perspective view illustrating a motor according to a first embodiment.

FIG. 2A is a plan view and FIG. 2B is across-sectional view taken along the line A-A′ shown in FIG. 2A, which illustrate the motor according to the first embodiment.

FIGS. 3A and 3B are schematic diagrams illustrating an operation of an actuator.

FIGS. 4A to 4C are schematic diagrams illustrating a relationship between the operation of the actuator and forces.

FIGS. 5A and 5B are plan views illustrating motors according to other embodiments.

FIG. 6 is an outer appearance diagram illustrating a robot hand according to a second embodiment.

FIG. 7 is an outer appearance diagram illustrating a robot according to a third embodiment.

### DESCRIPTION OF EXEMPLARY EMBODIMENTS

Hereinafter, exemplary embodiments of the invention will be described with reference to the drawings.

### First Embodiment

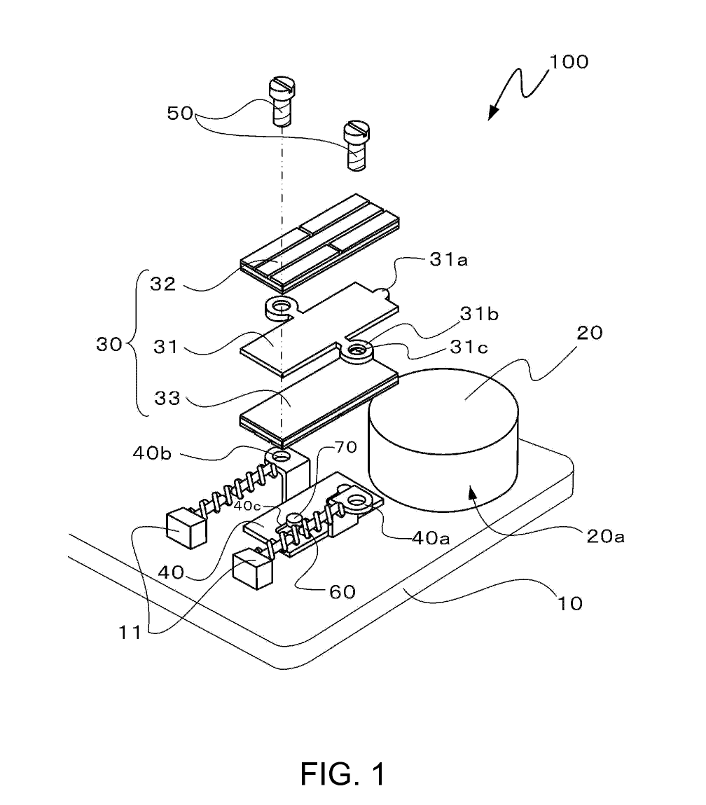

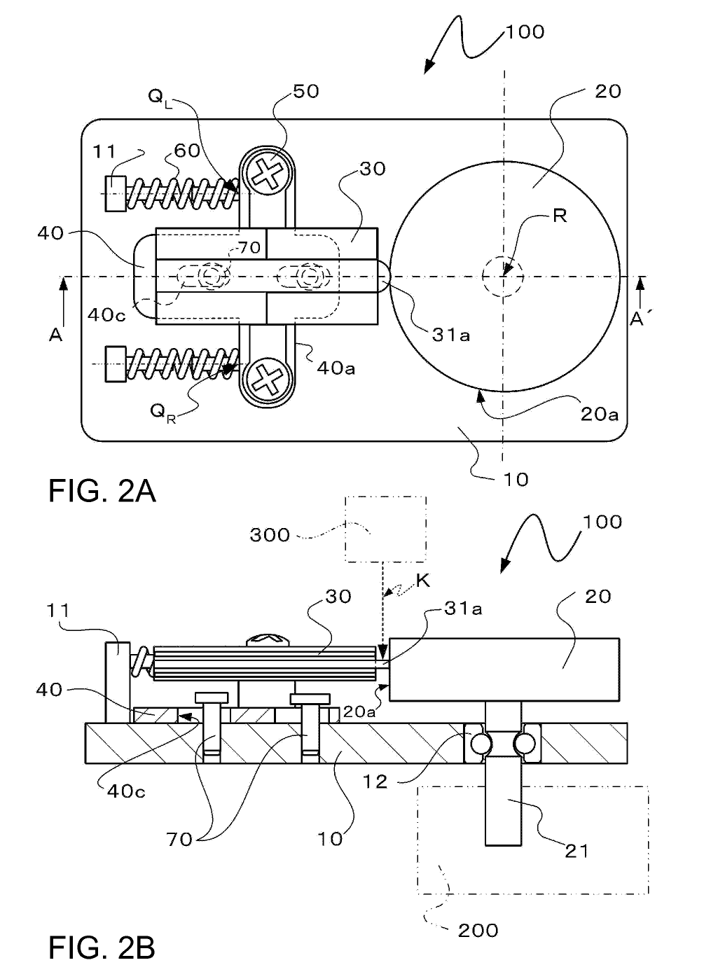

FIG. 1 is an exploded perspective view, FIG. 2A is an assembly plan view, and FIG. 2B is a cross-sectional view taken along the line A-A′ of FIG. 2A, which illustrate a motor 100 according to this embodiment. As illustrated in FIGS. 1, 2A, and 2B, the motor 100 includes a driven body 20 which is rotatably fixed to a base 10, a support body 40 which is slidably fixed to the base 10, a coil spring 60 as an impelling unit that impels the support body 40 against the driven body 20 side, and an actuator 30 which is fixed to the impelled support body 40 and drives the driven body 20 through vibration.

The actuator 30 is formed by bonding piezoelectric elements 32 and 33 made of rectangular piezoelectric bodies having electrodes formed therein with a vibrator plate 31 interposed therebetween. The piezoelectric elements 32 and 33 may use a material having piezoelectricity, for example, Lead Zirconate Titanate (PZT: Pb(Zr,Ti)O₃), quartz crystal, or Lithium Niobate (LiNbO₃). Particularly, PZT is appropriately used. The formed electrodes may be formed by depositing a conductive metal such as Au, Ti, or Ag and forming layers through sputtering or the like. The vibrator plate 31 has a protrusion 31a at the end portion, which is fixed to the support body 40 as the actuator 30, is impelled by the coil spring 60 against the driven body 20, and abuts on the driven body 20. In addition, the vibrator plate 31 is formed of stainless steel, nickel, a rubber metal, or the like, and due to workability, stainless steel is appropriately used. The actuator 30 is fixed to the support body 40 by screws 50 which are inserted through holes 31c of mounting portions 31b formed in the vibrator plate 31 for mounting to the support body 40 and are screwed into screw holes 40b of fixing portions 40a formed in the support body 40.

The driven body 20 has a cylindrical shape and is driven by the vibration of the actuator 30 as the protrusion 31a of the actuator 30 is impelled against and comes in contact with a cylindrical surface 20a due to the coil spring 60. In addition, as illustrated in FIG. 2B, the driven body 20 is fixed to the base 10 by a rotation unit including a rotation shaft 21 fixed to the driven body 20, a bearing 12, and the like. The rotational force of the rotation shaft 21 drives a driven device via a speed reduction or increasing device 200 (not shown) connected to the rotation shaft 21 at a desired rotational frequency or an output torque.

The support body 40 includes guide holes 40c, and guide pins 70 provided in the base 10 are inserted through the guide holes 40c such that the support body 40 is slidably fixed to the base 10. The shape of the guide hole 40c is a track shape in plan view in this embodiment so as to enable the support body 40 to slide in the impelling direction of the actuator 30, and is slightly greater than the outer diameter of the guide portion of the guide pin 70 in a direction intersecting the impelling direction of the actuator 30 so as to minimize the backlash amount in the direction intersecting the impelling direction of the actuator 30.

In addition, in the support body 40, the one end portions of the coil springs 60 as the impelling units are respectively fixed to two fixing portions 40a to which the actuator 30 is mounted. The other end portions of the coil springs 60 are mounted to spring mounting portions 11 provided on the base 10 so that the base body 40 is impelled in a direction of the driven body 20. In the support body 40, the mounting portion 31b of the vibrator plate 31 of the actuator 30 is placed on the fixing portion 40a of the support body 40, and the actuator 30 is fixed to the screw hole 40b provided in the fixing portion 40a by the screw 50. The protrusion 31a of the fixed actuator 30 is impelled against the driven body 20 by a predetermined force via the support body 40. In addition, the impelling unit is not limited to the coil spring 60, and for example, a leaf spring or an elastic rubber may also be used.

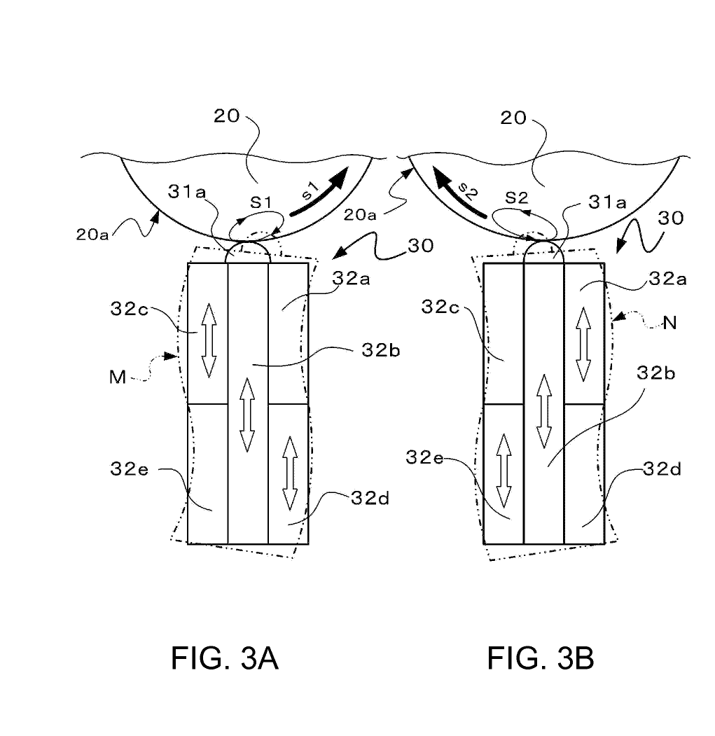

Next, the operation of the actuator 30 will be described with reference to FIGS. 3A and 3B. FIGS. 3A and 3B are schematic plan views illustrating a vibration operation of the actuator 30. As illustrated in FIG. 3A, from among electrodes 32a, 32b, 32c, 32d, and 32e formed in the piezoelectric element 32, an alternating voltage is applied between the electrodes 32c, 32b, and 32d and an electrode formed on the opposite side with a piezoelectric body (not shown) interposed therebetween, such that the piezoelectric body in a region where the electrodes 32c, 32b, and 32d are formed is excited to undergo longitudinal vibration in the direction of the illustrated arrow. In the region of the electrode 32b, the actuator 30 is longitudinally vibrated in the direction of the illustrated arrow, and in the regions of the electrodes 32c and 32d, the actuator 30 is excited to undergo flexural vibration indicated by a shape M. The protrusion 31a of the vibrator plate 31 is vibrated while tracing an elliptical trajectory S1.

In addition, as illustrated in FIG. 3B, from among electrodes 32a, 32b, 32c, 32d, and 32e formed in the piezoelectric element 32, an alternating voltage is applied between the electrodes 32a, 32b, and 32e and an electrode formed on the opposite side with a piezoelectric body (not shown) interposed therebetween, such that the piezoelectric body in a region where the electrodes 32a, 32b, and 32e are formed is excited to undergo longitudinal vibration in the direction of the illustrated arrow. In the region of the electrode 32b, the actuator 30 is longitudinally vibrated in the direction of the illustrated arrow, and in the regions of the electrodes 32a and 32e, the actuator 30 is excited to undergo flexural vibration indicated by a shape N. The protrusion 31a of the vibrator plate 31 is vibrated while tracing an elliptical trajectory S2.

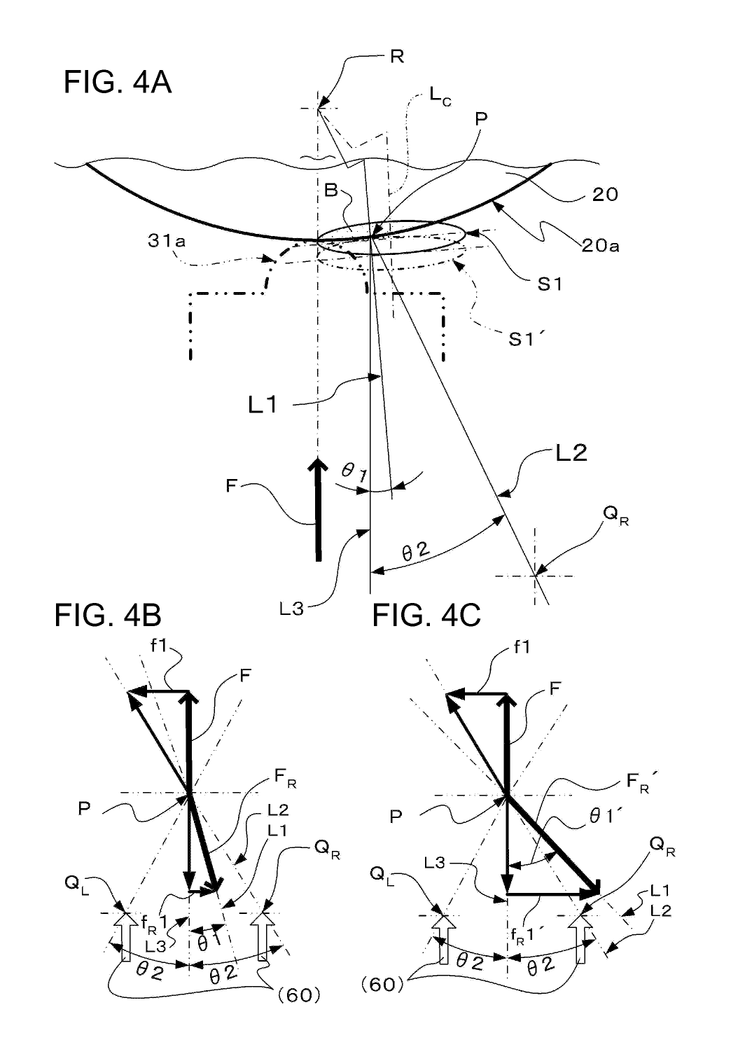

The elliptical trajectories S1 and S2 of the protrusion 31a that are generated by the vibration of the actuator 30 described above are impelled against and come in contact with the driven body 20 due to the impelling force and thus drive the driven body 20 in the directions of illustrated arrows s1 and s2. The relationship among the elliptical trajectories S1 and S2, the driven body 20, the coil spring 60 as the impelling unit, and the support body 40 will be described with reference to FIGS. 4A to 4C.

FIG. 4A is a conceptual view for explanation using the elliptical trajectory S1 illustrated in FIG. 3A. As illustrated in FIG. 2A, assuming that the rotational center of the driven body 20 is R and impelling points where the coil springs 60 impel the fixing portions 40a of the support body 40 are Q_{R} and Q_{L}, it is preferable that the driven body 20 and the actuator 30 have a relationship as shown in FIG. 4A.

As illustrated in FIG. 4A, the elliptical trajectory S1 traced by the protrusion 31a of the actuator 30 traces a trajectory forming an overlap B of a hatched portion on the cylindrical surface 20a of the outer shape of the driven body 20. The overlap B does not overlap in practice due to the displacement of the coil spring 60, the deformation of the materials of the actuator 30 and the driven body 20, and the like during driving of the motor 100. An elliptical trajectory figure formed when the elliptical trajectory S1 is moved along a straight line L_{C} connecting the center of the elliptical trajectory S1 and the rotational center R of the driven body 20 until the cylindrical surface 20a of the driven body 20 abuts on the trajectory figure of the elliptical trajectory S1 is referred to as an elliptical trajectory S1′. A contact point between the elliptical trajectory S1′ and the cylindrical surface 20a of the driven body 20 is defined as a contact point P.

Assuming that a straight line connecting the rotational center R of the driven body 20 and the contact point P is L1 and a straight line connecting the contact point P and the impelling point Q_{R} is L2, it is preferable that an angle θ1 between a straight line L3 passing through the contact point P in parallel to the illustrated impelling direction of an impelling force F by the coil spring 60 as the impelling unit, and the straight line L1 and an angle θ2 between the straight line L3 and the straight line L2 satisfy the following relationship.

θ1<θ2 (1)

FIG. 4B is a conceptual view illustrating the relationship between the impelling force F at the contact point P and a reaction force F_{R} exerted on the protrusion 31a of the actuator 30 from the cylindrical surface 20a of the driven body 20. As illustrated in FIG. 4B, the impelling force F may be resolved into a component force along the straight line L2 and a component force f1 orthogonal to the straight line L3. In addition, the reaction force F_{R} may be resolved into a component force of the straight line L3 and a component force f_{R}1 orthogonal to the impelling direction. Since the angles θ1 and θ2 have the relationship of Expression (1), the relationship becomes as follows.

f1>f_{R}1

The difference between the component forces f1 and f_{R}1 is exerted so that the impelling force F due to the coil spring 60 impels the protrusion 31a against the rotational center R of the driven body 20.

That is, from the relationship of the angles θ1 and θ2 shown in Expression (1), the component force f_{R}1 of the impelling force generated by the reaction force F_{R} that does not cause the protrusion 31a to be directed to the rotational center R is suppressed, and the vibration of the excited actuator 30 may be converted into rotational force of the driven body 20 with high efficiency.

FIG. 4C is a conceptual view illustrating the case of the following relationship.

θ1′>θ2 (2)

In addition, the angle θ1′ in FIG. 4C and Expression (2) corresponds to the angle θ1 in FIG. 4B and Expression (1). As illustrated in FIG. 4C, in the case of the relationship of the angles θ1′ and θ2 expressed in Expression (2), a component force f_{R}1′ orthogonal to the straight line L3 of a reaction force F_{R}′ has the following relationship.

f1<f_{R}1′

When the relationship of the angles θ1′ and θ2 shown in Expression (2) is satisfied, the component force f_{R}1′ of the impelling force generated by the reaction force F_{R}′ that does not cause the protrusion 31a to be directed to the rotational center R cannot be suppressed by the component force f1 of the impelling force F, and an efficiency in converting the vibration of the excited actuator 30 into the rotational force of f the driven body 20 is significantly damaged. In addition, even in the case of the elliptical trajectory S2 shown in FIG. 3B, similar to the above description, the impelling point Q_{R} is only substituted by the impelling point Q_{L} shown in FIG. 2A, so that description thereof is omitted.

The above-described elliptical trajectories S1 and S2 may be measured by the following method. The motor 100 according to this embodiment is driven, reflected light of a laser beam K emitted toward the protrusion 31a in the direction shown in FIG. 2B by a measurement device 300 (Optical Heterodyne Micro Vibration Measuring unit MLD-103A, manufactured by NEOARK Corporation) is received by the measurement device 300, and data measured by the measurement device 300 is displayed as waveforms on an oscilloscope (YOKOGAWA DL-716, manufactured by Yokogawa Electric Corporation) or is processed by a computer, thereby measuring the elliptical trajectories S1 and S2.

While checking the elliptical trajectories S1 and S2 measured as such, by changing the dimensions of each of the piezoelectric elements 32 and 33 of the actuator 30, the driving voltage, the impelling force of the coil spring 60, the arrangement position of the actuator 30, the material of the piezoelectric elements 32 and 33, the material of the driven body 20, surface finish of the cylindrical surface 20a, and the like, the motor 100 that satisfies the conditions of Expression (1) is manufactured.

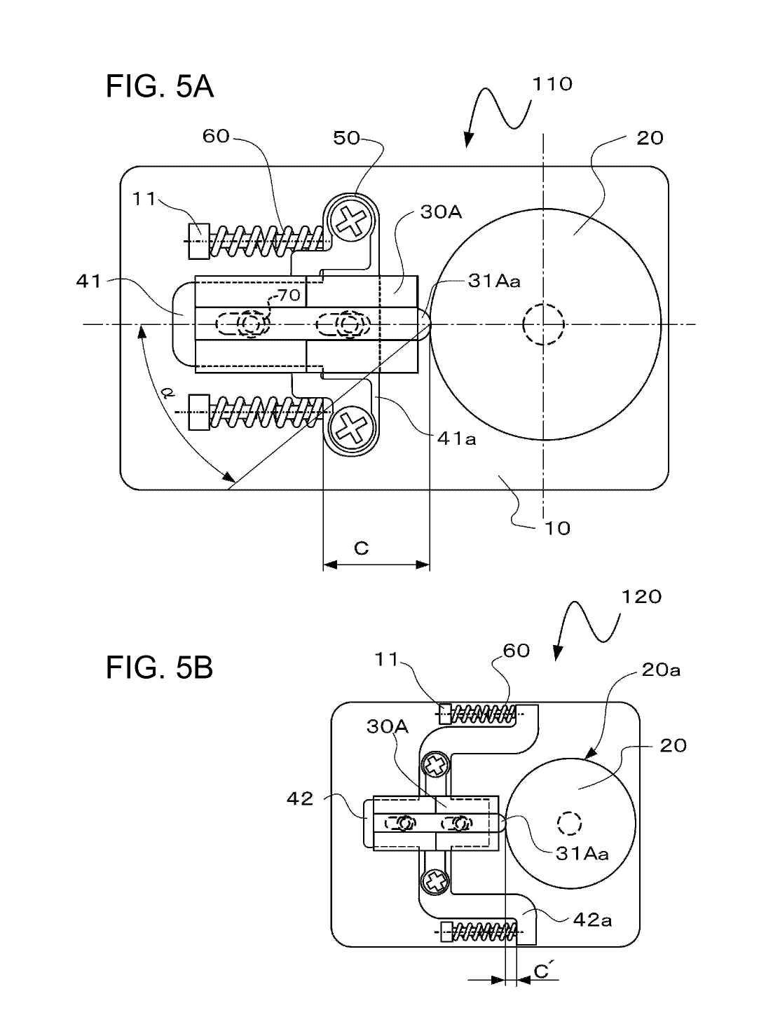

By the arrangements of the impelling unit as illustrated in FIGS. 5A and 5B, the angle θ2 in Expression (1) may be increased, so that the degree of freedom of the angle θ1 shown in FIGS. 4A, 4B and Expression (1) may be easily increased. In a motor 110 illustrated in FIG. 5A, a fixing portion 41a of a support body 41 is disposed at a position close to a protrusion 31Aa of an actuator 30A, that is, a dimension C is disposed to be smaller than that of the motor 100 illustrated in FIGS. 2A and 2B. Accordingly, an angle α approximating the angle θ2 is further increased, and thus a large angle of θ2 may be obtained, thereby increasing the degree of freedom of the angle θ1.

In addition, in a motor 120 illustrated in FIG. 5B, an impelling point of the coil spring 60 against a fixing portion 42a of a support body 42 is disposed at a position of C′ on the rotational center side of the driven body 20 from the position of the protrusion 31Aa of the actuator 30A. By disposing the impelling point as described above, the limitations on the dimensions of each of the piezoelectric elements of the actuator 30A, the driving voltage, the impelling force of the coil spring 60, the arrangement position of the actuator 30A, the material of the piezoelectric elements, the material of the driven body 20, surface finish of the cylindrical surface 20a, and the like, for determining the angle θ1 shown in FIGS. 4A and 4B may be significantly reduced.

### Second Embodiment

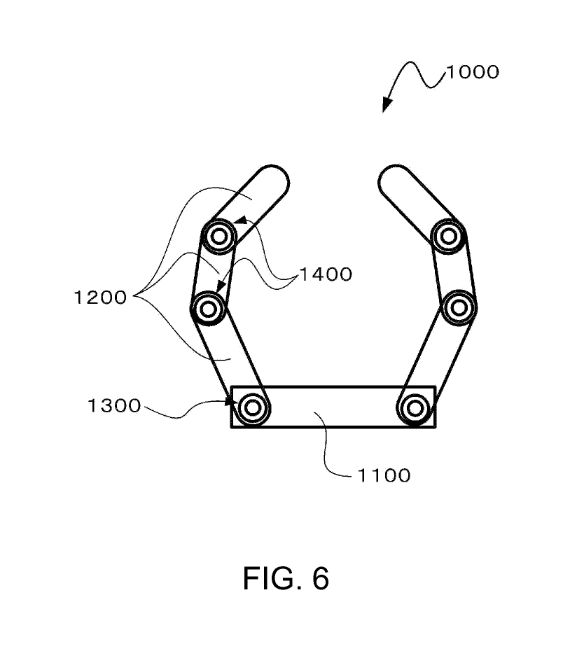

FIG. 6 is an outer appearance diagram illustrating a robot hand 1000 having the motor 100 according to a second embodiment. The robot hand 1000 includes a base portion 1100 and finger portions 1200 connected to the base portion 1100. The motor 100 is assembled into a connection portion 1300 between the base portion 1100 and the finger portion 1200, and into a joint portion 1400 of the finger portion 1200. As the motor 100 is driven, the finger portion 1200 is bent and can hold an object. Using the motor 100 which is a micro motor, a robot hand having a number of small motors may be realized.

### Third Embodiment

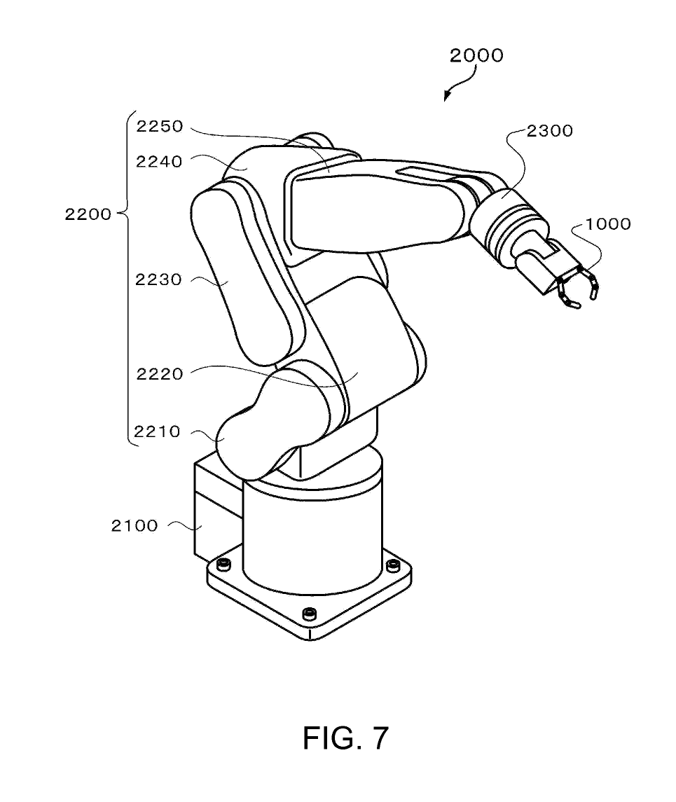

FIG. 7 is a diagram illustrating the construction of a robot 2000 having the robot hand 1000. The robot 2000 includes a main body portion 2100, an arm portion 2200, the robot hand 1000, and the like. The main body portion 2100 is fixed on, for example, a floor, a wall, a ceiling, or a movable carriage. The arm portion 2200 is provided to be movable with respect to the main body portion 2100, and into the main body portion 2100, an actuator (not shown) generating the power to rotate the arm portion 2200, a control unit controlling the actuator, and the like are embedded.

The arm portion 2200 includes a first frame 2210, a second frame 2220, a third frame 2230, a fourth frame 2240, and a fifth frame 2250. The first frame 2210 is rotatably or bendably connected to the main body portion 2100 with a rotation bending shaft. The second frame 2220 is connected to the first and third frames 2210 and 2230 via a rotation bending shaft. The third frame 2230 is connected to the second and fourth frames 2220 and 2240 via a rotation bending shaft. The fourth frame 2240 is connected to the third and fifth frames 2230 and 2250 via a rotation bending shaft. The fifth frame 2250 is connected to the fourth frame 2240 via a rotation bending shaft. The arm portion 2200 is moved as the frames 2210 to 2250 are complexly rotated or bent about the corresponding rotation bending shafts under the control of the control unit.

To the side of the fifth frame 2250 of the arm portion 2200 opposite to the side where the fourth frame 2240 is provided, a robot hand connection portion 2300 is connected, and the robot hand 1000 is mounted to the robot hand connection portion 2300. The motor 100 that causes the robot hand 1000 to perform a rotation operation is embedded into the robot hand connection portion 2300, so that the robot hand 1000 can grasp an object. Using the robot hand 1000 which is small in size and weight, a robot which has a high degree of versatility and is able to perform an assembly operation, inspection, or the like on a complex electronic device may be provided.

The entire disclosure of Japanese Patent Application No. 2011-125103, filed Jun. 3, 2011 is expressly incorporated by reference herein.

What is claimed is:

1. A motor comprising:
a driven unit having a cylindrical rotation surface;
an actuator including a vibrator plate having, on an end portion, a protrusion impelled against the rotation surface of the driven unit, and a piezoelectric body laminated on the vibrator plate; and
an impelling unit impelling the actuator against the driven unit,
wherein, assuming that an elliptical trajectory of the protrusion traced by vibration of the actuator that drives the driven unit is disposed to abut on the rotation surface, a contact point between the elliptical trajectory and the rotation surface is a contact point P, a point of action where an impelling force by the impelling unit is exerted on the actuator is a point of action Q, and a rotational center of the driven unit is a rotational center R, an angle θ1 between an impelling direction of the impelling unit and a direction connecting the rotational center R and the contact point P and an angle θ2 between the impelling direction of the impelling unit and a direction connecting the contact point P and the point of action Q satisfy the following relationship:
θ1<θ2.

2. A robot hand comprising the motor according to claim 1.

3. A robot comprising the robot hand according to claim 2.

4. A motor comprising:
a cylindrical driven unit having a rotational center, and a cylindrical surface formed by points at the same distance from the rotational center as a rotation surface;
an actuator including a piezoelectric body and a protrusion abutting on the driven unit; and
an impelling unit impelling the actuator against the driven unit,
wherein, assuming that a trajectory of the protrusion traced when the actuator is vibrated and the rotation surface are disposed to abut on each other, a contact point between the trajectory and the rotation surface is a contact point P, a point of action where an impelling force by the impelling unit is exerted on the actuator is a point of action Q, and a rotational center of the driven unit is a rotational center R, an angle θ1 between an impelling direction of the impelling unit and a direction connecting the rotational center R and the contact point P and an angle θ2 between the impelling direction of the impelling unit and a direction connecting the contact point P and the point of action Q satisfy the following relationship:
θ1<θ2.

5. A robot hand comprising:
a cylindrical driven unit having a rotational center, and a cylindrical surface formed by points at the same distance from the rotational center as a rotation surface;
an actuator including a piezoelectric body and a protrusion abutting on the driven unit;
an impelling unit impelling the actuator against the driven unit; and
a plurality of finger portions,
wherein, assuming that a trajectory of the protrusion traced when the actuator is vibrated and the rotation surface are disposed to abut on each other, a contact point between the trajectory and the rotation surface is a contact point P, a point of action where an impelling force by the impelling unit is exerted on the actuator is a point of action Q, and a rotational center of the driven unit is a rotational center R, an angle θ1 between an impelling direction of the impelling unit and a direction connecting the rotational center R and the contact point P and an angle θ2 between the impelling direction of the impelling unit and a direction connecting the contact point P and the point of action Q satisfy the following relationship:
θ1<θ2.

6. A robot comprising:
a cylindrical driven unit having a rotational center, and a cylindrical surface formed by points at the same distance from the rotational center as a rotation surface;
an actuator including a piezoelectric body and a protrusion abutting on the driven unit;
an impelling unit impelling the actuator against the driven unit; and
an arm portion having a rotatable joint portion,
wherein, assuming that a trajectory of the protrusion traced when the actuator is vibrated and the rotation surface are disposed to abut on each other, a contact point between the trajectory and the rotation surface is a contact point P, a point of action where an impelling force by the impelling unit is exerted on the actuator is a point of action Q, and a rotational center of the driven unit is a rotational center R, an angle θ1 between an impelling direction of the impelling unit and a direction connecting the rotational center R and the contact point P and an angle θ2 between the impelling direction of the impelling unit and a direction connecting the contact point P and the point of action Q satisfy the following relationship:
θ1<θ2.
